(19) United States
(12) Patent Application Publication
(10) Pub. No.: US 2004/0150099 A1
(43) Pub. Date: Aug. 5, 2004

(54) Cavity down MCM package

(75) Inventors: Yi-Chuan Ding, Kaohsiung (TW); Yung-I Yeh, Kaohsiung (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/747,191

(22) Filed: Dec. 30, 2003

(30) Foreign Application Priority Data
Dec. 31, 2002 (TW) 091138170

(51) Int. Cl. H01L 23/34

(52) U.S. Cl. 257/712

(57) ABSTRACT

A cavity down multi-chips module package mainly comprises a substrate, a heat spreader, a plurality of chips and a carrier. The heat spreader is attached on the substrate via an adhesive so as to define a cavity through the opening passing through the substrate, and the carrier for redistributing electrical signals is disposed in the opening so as to be mounted on the heat spreader through another adhesive. Moreover, a plurality of chips are attached on the carrier and electrically connected to the carrier through first electrically conductive wires. Besides, the carrier is electrically connected to the substrate through second electrically conductive wires. Accordingly, the electrical signals can be transmitted from the chips to the substrate through the carrier, the first wires, and the second wires so as to shorten the electrical paths and to upgrade the electrical performance of the package.

### BACKGROUND OF THE INVENTION

1. Field of Invention

This invention relates to a cavity down multi-chips module (MCM) package. More particularly, the present invention is related to a cavity down MCM package with a carrier, formed in a cavity, for redistributing electrical signals.

2. Related Art

Recently, integrated circuit (chip) packaging technology is becoming a limiting factor for the development in packaged integrated circuits of higher performance. Semiconductor package designers are struggling to keep pace with the increase in pin count, size limitations, low profile, and other evolving requirements for packaging and mounting integrated circuits.

Generally speaking, ball grid array assembly (BGA) packages comprise conventional BGA packages, cavity up BGA packages and cavity down BGA packages. As shown in FIG. 1, the cavity down BGA package mainly comprises a chip 10, a substrate 11 and a heat spreader 12. The substrate 11 has an opening 111 formed therein and is disposed on a heat spreader 12 so as to define a cavity. In addition, the chip 10 is disposed on the upper surface 121 of the substrate via an adhesive 17, for example a thermally conductive epoxy, so as to be accommodated in the opening 111.

Next, referring to FIG. 1 again, the bonding pad 102 formed on the active surface 101 of the chip 10 is electrically connected to the wire-bonding pad 113 at the periphery of the opening 111. Moreover, the lower surface 112 of the substrate 11 has a plurality of solder ball pads 114 which surround the wire-bonding pads 113 and are electrically connected to external electronic devices (not shown). In addition, there is further provided an encapsulation 16 covering the chip 10, the electrically conductive wires 14 and the opening 111 of the substrate 11. Furthermore, the encapsulation 16 may cover a portion of the lower surface 112 of the substrate 11.

Due to the assembly package in miniature and the integrated circuits operation in high frequency, MCM (multi-chips module) packages are commonly used in said assembly packages and electronic devices. Accordingly, the cavity may accommodate a plurality of chips 20 to form a cavity down MCM package as shown in FIG. 2. However, in such a package design, the length of one of the electrically conductive wires 24 for connecting the bonding pad 202 and the wire-bonding pad of the substrate will be extended, and the layout for the wires 24 will become more complex. Consequently, the electrical performance will be lowered and the wire-bonding process will be operated more difficultly.

Therefore, providing another assembly package to solve the mentioned-above disadvantages is the most important task in this invention.

### SUMMARY OF THE INVENTION

In view of the above-mentioned problems, an objective of this invention is to provide a cavity down MCM package with a redistributed carrier, formed in a cavity, for redistributing electrical signals.

To achieve the above-mentioned objective, a cavity down multi-chips module (MCM) package is provided, wherein said package mainly comprises a substrate, a heat spreader, a plurality of chips and a carrier for redistributing electrical signals. The substrate has an opening and is attached to the heat spreader so as to define a cavity for accommodating the carrier mounted on the heat spreader. In addition, the chips are disposed on the carrier and electrically connected to the carrier via a plurality of first electrically conductive wires and second electrically conductive wires.

As mentioned above, the first electrically conductive wires electrically connect the carrier and the chips, and the second electrically conductive wires electrically connect the chips and the substrate. Therein, the carrier has a redistributed circuit layer formed therein for electrically connecting the chips and the substrate so as to transmit the electrical signals from the chips to the substrate. Then, the electrical signals can be transmitted to external devices. Accordingly, the electrical performance of said package will be upgraded due to shorten the electrical paths.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional cavity down package;

FIG. 2 is a cross-sectional view of a conventional cavity down MCM package;

FIG. 3 is a cross-sectional view of a cavity down MCM package according to the first embodiment;

FIG. 4 is a cross-sectional view of the carrier for redistributing electrical signals according to FIG. 3; and

FIG. 5 is a cross-sectional view of a cavity down MCM package according to the second embodiment.

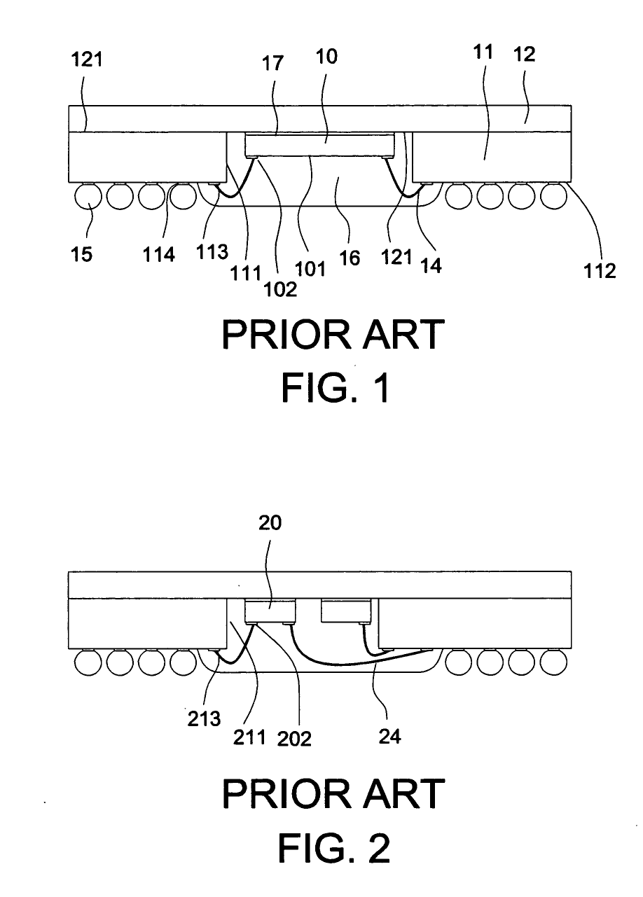

### DETAILED DESCRIPTION OF THE INVENTION

The cavity down MCM package according to the preferred embodiment of this invention will be described herein below with reference to the accompanying drawings, wherein the same reference numbers refer to the same elements.

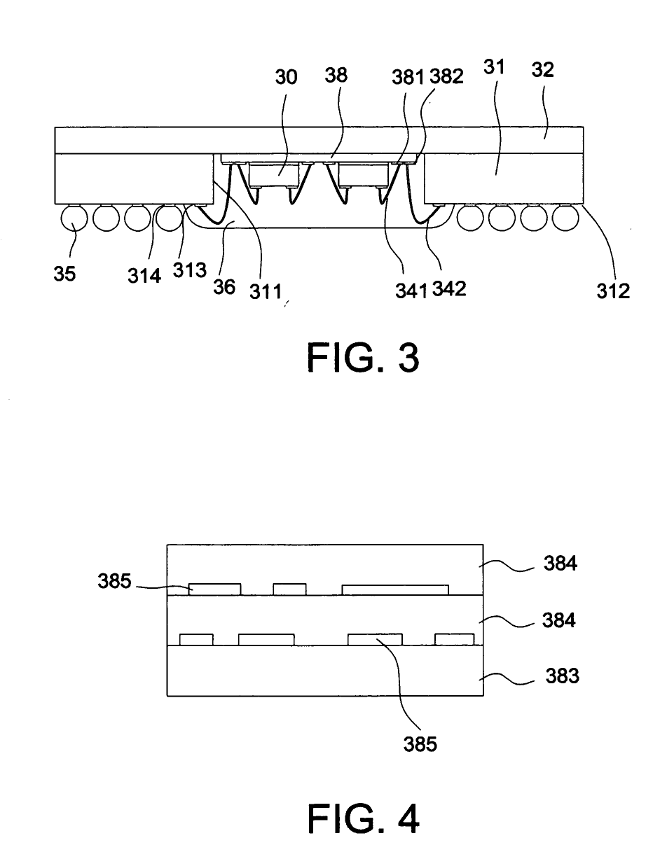

In accordance with a first preferred embodiment as shown in FIG. 3, there is provided a cavity down MCM package. Said cavity down MCM package mainly comprises a plurality of chips 30, a substrate 31, a heat spreader 32 and a carrier 38. Therein, the substrate 31 has a lower surface 312 and an opening 311 formed at the lower surface 312. The substrate 31 is disposed on the heat spreader 32 to define a cavity. Moreover, the upper surface 312 further has a plurality of wire-bonding pads 313 surrounding the opening 311 and located at the periphery of the opening 311, wherein the wire-bonding pads 313 are electrically connected to solder ball pads 314. And the solder ball 35 is disposed on one of the solder ball pads 314 for electrically connecting external devices. In addition, the chips 30 are disposed on the carrier 38 by attaching the back surfaces of the chips 30 to the carrier 38 via an adhesive, and the first electrically conductive wires 341 connect the one of the bonding pads and the first redistribution pad 381. The second electrically conductive wires 341 connect the wire-bonding pads 313 of the substrate and the second redistribution pads 382. Furthermore, there is further provided an encapsulation 36 covering the chips 30, the first electrically conductive wires 341, the second electrically conductive wires 342 and the opening 311 of the substrate 31. It should be noted that the reference numeral of each element shown in FIG. 3 are corresponding the reference one provided in FIG. 2.

As mentioned above, the carrier 38 comprises a plurality of insulating layers 384 and a plurality of circuit layers 385 interlaced with each other and disposed on a core layer 383 as shown in FIG. 4. In addition, the substrate 31 is attached to the heat spreader 32 via an adhesive. Therein, the adhesive may be a thermally conductive epoxy and the material of the insulating layers may be selected from Bismaleimide-Triazine (BT), glass epoxy resins (FR4) and polyimide (PI). In addition, the circuit layer 385 may be made of copper metal. Besides, the first redistribution pad 381 and the second redistribution pad 382 are electrically connected with each other by the circuit layer 385. In such a manner, the electrical signals can be transmitted from the chips 30 to the substrate 31 via the carrier 38.

Besides, as mentioned above, the carrier 38 can be formed by the method of build-up method to have a plurality of circuit layers and insulating layers interlaced with each other and directly attach onto the heat spreader 32. The above-mentioned process may include the steps of defining a cavity 33 by attaching the substrate with an opening onto the heat spreader 32, disposing an insulating layer, for example Benzocyelobutene (BCB) layer, in the cavity 311 and attached onto the heat spreader 32 directly and then a metal foil is formed on the insulation layer. Afterwards, the process of forming a photo-resist layer, for example a dry film, on the metal layer is performed. Then, processes of exposure, photolithography and etching are performed to form a patterned circuit layer on the insulation layer. Then, a plurality of circuit layers are formed by repeating the above-mentioned process.

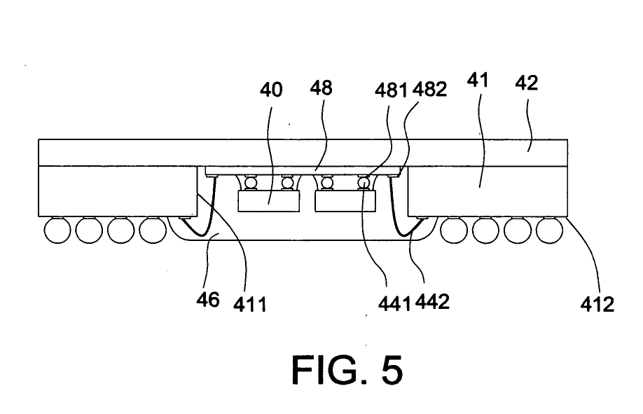

As mentioned above and referring to FIG. 5, there is provided a second preferred embodiment according to this invention. Chips 40 are mounted on the carrier 48 via a plurality of electrically conductive bumps 441, for example solder bumps, to electrically connect with a first redistributed pad 481 of the carrier 48 by flip-chip bonding, wherein the first redistributed pad 481 is electrically connected to the second redistributed pad 482 through the circuit layer of the carrier 48. In addition, the second redistributed pad 482 is electrically connected to the bonding pad 413via electrically conductive wires 442. Besides, there is provided another encapsulation 46 covering the chips 40, the electrically conductive bumps 441, the electrically conductive wires 442 and the opening 411 of the substrate 41. Therein, the encapsulation 46 may further cover a portion of the lower surface 412 of the substrate 41.

Although the invention has been described in considerable detail with reference to certain preferred embodiments, it will be appreciated and understood that various changes and modifications may be made without departing from the spirit and scope of the invention as defined in the appended claims.

What is claimed is:

1. A cavity down multi-chips module package, comprising:
a heat spreader;
a substrate having an upper surface, a lower surface and an opening passing through the upper surface and the lower surface, wherein the upper surface of the substrate is disposed onto the heat spreader and a portion of the heat spreader exposes the opening so as to define a cavity;
a carrier disposed in the cavity and mounted on the heat spreader;
a plurality of chips disposed on and electrically connected to the carrier; and
a plurality of electrically conductive wires connecting the carrier and the substrate.

2. The multi-chips module package of claim 1, further comprising an encapsulation covering the chips and the electrically conductive wires.

3. The multi-chips module package of claim 1, wherein the chips are wire-bonded to the carrier.

4. The multi-chips module package of claim 1, wherein the chips are mounted on the carrier through bumps.

5. The multi-chips module package of claim 1, wherein the carrier comprises insulation layers and circuit layers, and the insulation layers are interlaced with the circuit layers.

6. The multi-chips module package of claim 5, further comprising an adhesive interposed between the upper surface of the substrate and the carrier.

7. The multi-chips module package of claim 6, wherein the adhesive is a thermally conductive epoxy.

8. The multi-chips module package of claim 5, wherein the insulation layer is made of Bismaleimide-Triazine.

9. The multi-chips module package of claim 5, wherein the insulation layer is made of glass epoxy resin.

10. The multi-chips module package of claim 5, wherein the insulation layer is made of polyimide.

11. The multi-chips module package of claim 5, wherein the insulation layer is made of Benzocyelobutene.

12. The multi-chips module package of claim 5, wherein the circuit layer is made of copper metal.

13. The multi-chips module package of claim 5, wherein the insulation layers and the circuit layers are formed on the heat spreader by a build-up method.

14. The multi-chips module package of claim 13, wherein one of the insulation layers is directly disposed on the heat spreader.

15. The multi-chips module package of claim 1, wherein the substrate further comprises a plurality solder ball pads formed on the lower surface.

16. The multi-chips module package of claim 15, further comprising a plurality of solder balls formed on the solder ball pads.

17. The multi-chips module package of claim 4, wherein the chips are electrically connected to the carrier through bumps.

18. The multi-chips module package of claim 1, further comprising an adhesive interposed between the heat spreader and the carrier.
